(19) United States
(12) Patent Application Publication
(10) Pub. No.: US 2024/0217391 A1
(43) Pub. Date: Jul. 4, 2024

(54) System and Method Implementing a Battery Avionics System for Electric-Powered Aircraft

(71) Applicant: CARNEGIE MELLON UNIVERSITY, Pittsburgh, PA (US)

(72) Inventors: Venkatasubramanian Viswanathan, Pittsburgh, PA (US); Alexander Bills, Pittsburgh, PA (US); Shashank Sripad, Pittsburgh, PA (US)

(73) Assignee: CARNEGIE MELLON UNIVERSITY, Pittsburgh, PA (US)

(21) Appl. No.: 18/563,433

(22) PCT Filed: May 31, 2022
(86) PCT No.: PCT/US22/31504

§ 371 Date: Nov. 22, 2023

Related U.S. Application Data
(60) Provisional application No. 63/196,870, filed on Jun. 4, 2021.

(51) Int. Cl. B60L 58/18; B64D 27/357; G06F 30/20; H01M 10/42; H02J 7/00

(52) U.S. Cl. CPC B60L 58/18; B64D 27/357; G06F 30/20; H01M 10/425; H02J 7/0047; H02J 7/0063; B60L 2200/10; H01M 2010/4271; H01M 2220/20

(57) ABSTRACT

Disclosed herein is a system and method implementing a battery avionics system for integrating battery monitoring, control, and management functions with an avionics system of an aircraft. The system uses a model implementing a battery pack digital twin, which is a continuous simulation of the operation of the battery pack within the aircraft, receives data regarding the battery pack generated by the digital twin model and provides optimized parameters to the battery avionics system. The system enables high precision, cell-level resolution control of the battery pack. The system estimates the state of charge, state of health, state of safety, and state of function of the cells and the battery pack as a whole and uses this information to manage the battery pack, given a particular flight profile of the aircraft.

### RELATED APPLICATIONS

This application claims the benefit of U.S. Provisional Patent Application No. 63/196,870 filed Jun. 4, 2021, the contents of which are incorporated herein in their entirety.

### BACKGROUND OF THE INVENTION

Urban air mobility (UAM), enabled by electric vertical takeoff and landing (EVTOL) aircraft, is limited by the range, usable life, and safety considerations of the battery pack which provides power for both propulsion and other sub-systems of the aircraft (avionics, communication, flight planning, etc.). Recent EVTOL designs have demonstrated 40% less energy-intensive and 10 times faster mobility compared to terrestrial electric vehicles. Further, EVTOL aircraft can have lower emissions than terrestrial EV's.

Improving the operational capabilities of EVTOLs is critical for market penetration. Simultaneously, disruptive advances in battery materials and engineering have resulted in continuously improving performance metrics. Thus, EVTOLs will use batteries whose chemistries will change rapidly with time. To ensure safe and optimal operation, aircraft will need a variety of battery models and management architectures. These architectures must be flexible to account for new technologies that arise over the service life of an aircraft. Along with improving performance metrics, new chemistries also bring new failure and degradation modes.

Battery packs used fully or partially for propulsion in aircraft require monitoring, control, and management systems, generally referred to as battery management systems, to ensure safe and reliable operation. The monitoring, control, and management systems for propulsion batteries incur significant costs, add weight to the aircraft, influence the performance of the aircraft, inform the certification process for the battery pack and of the entire aircraft, and inform the salvage value of the battery pack.

Aircraft utilize several electronics on-board avionics platforms performing several functions including, for example, navigation, communication, control, flight planning, fuel planning, etc. These functions fulfill the requirements necessary to ensure safe and reliable operation of the aircraft. Fuel/thrust avionics and engine monitoring for traditional jet-engine aircraft are routinely used in trajectory planning, ensuring safe propulsion, and optimizing other operations like refueling and maintenance of reserves.

Current aircraft feature fully-integrated fuel planning and engine monitoring functionality in the avionics. These features are even more important for electric aircraft because the amount of available power changes with battery discharge, which may be dependent on many factors, including state of charge, but temperature, state of charge, and state of health including capacity and internal resistance.

Available energy is not easily measurable and can change considerably through battery degradation over the lifetime of the cells in the battery pack. Current battery management systems, however, do not provide similar levels of integration into the avionics systems of conventional aircraft.

Therefore, it is desirable to provide a battery management system to improve the performance of batteries used partially or fully for propulsion of aircraft, to improve metrics for certification, and to enable accurate estimation of the internal states of the battery pack to improve performance and assess the salvage value of the battery pack, including individual cells within.

### SUMMARY OF THE INVENTION

The invention described herein relates generally to the field of managing the power, thermal, and safety related performance of batteries for use in electric aircraft.

Described herein is an approach for integrating the battery monitoring, control, and management systems with the aircraft avionics systems resulting in a “Battery Avionics System” (BAS).

The BAS utilizes two approaches: (1) a battery pack digital twin, which is a model providing a continuous simulation of the operation of the battery pack within the aircraft and which is configured to transmit signals from the battery pack digital twin platform to the aircraft; and (2) digital cell specification objects, which contain electrochemical and thermal performance metrics and material composition of the cells of the battery pack.

The BAS uses data received from the battery pack digital twin to execute high precision, cell-level resolution control. The BAS and the digital twin estimate the state of charge, state of health, state of safety, and state of function of the cells and the battery pack as a whole. This presents significant performance and financial benefits to operators and manufacturers of electric aircraft.

### Definitions

As used herein, including as used in the claims, the term “aircraft” should be interpreted to mean any vehicle (manned or unmanned) deriving its power for propulsion, either partially or fully, via one or more on-board battery packs, including, but not limited to, winged aircraft, drones, helicopters, spacecraft, submarines and terrestrial vehicles.

### BRIEF DESCRIPTION OF THE DRAWINGS

FIG. 1 is a schematic representation of the closed loop approach of the battery avionics system (BAS) featuring the use of digital spec-sheets, battery pack digital twins, and other functions.

FIG. 2 is a schematic representation of the three main tasks of the BAS.

### DETAILED DESCRIPTION

To improve the range, usable life, and safety, and to realize the commercial viability of EVTOL aircraft, disclosed herein is the Battery Avionics System (BAS) which leverages digital specification sheets for next-generation batteries paired with a cloud-based battery pack digital twin on-ground.

An electric aircraft may typically be equipped with a battery pack that may contain between 5,000 and 10,000 cells. As would be realized, not all of the cells will behave the same and the way that they behave may change over their lifetime. Typically, there is a battery management system on board the aircraft. By updating the battery management system to a battery avionics system (BAS), other systems aboard the aircraft can be updated with new information from data that is gathered from the battery pack. The data gathered on the aircraft can be processed and the BAS can use this information to better manage the batteries. For example, the information provided enables better estimates of remaining charge or power or how to best control how the batteries are charged (faster charge, slower charge, etc.). In one embodiment, information collected in the aircraft can be processed on the ground using a cloud-based system implementing the battery pack digital twin models.

The BAS provides real-time monitoring and control of the internal states of function, health, and safety of an airborne battery pack along with integrated trajectory and re-charge planning. Digital specification sheets allow for quick integration of novel chemistries, such as the Li-metal-anodes and conversion cathodes.

The BAS framework presents a radical departure through real-time pack state estimation and monitoring at cell-level resolution enabling utilization of advanced sensing technologies. The eventual adoption of electric aircraft will feature advanced levels of connectivity and automation and the on-ground battery pack digital twin will be a critical piece in UAM fleet air traffic management for ensuring fleet-level safety and energy-efficient operation, along with re-charging and trajectory planning to extend battery pack life, which is crucial to the economics of electric aircraft.

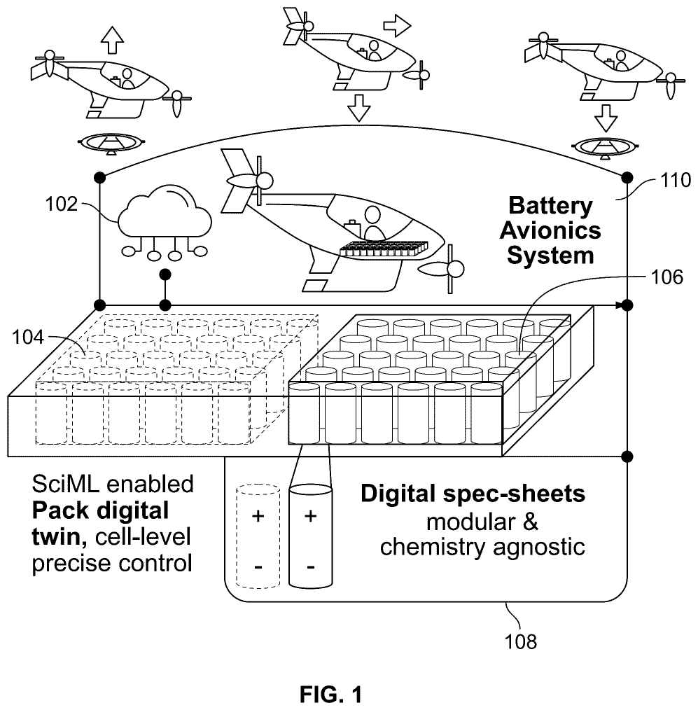

The BAS platform includes three parts that address the needs of the electric aircraft operators and manufacturers and significantly advances the capabilities of electric aircraft for UAM. FIG. 1 is a schematic representation the the components of the BAS platform.

Model-Based BAS: Current battery management systems idealize the battery pack 106 by either lumping the cells together or by designing the battery management system around the weakest cell in the pack, thereby losing crucial information on the internal states of the individual in-pack cells, such as state of charge, state of health, state of safety, state of function, and temperature.

BAS 110 provides the pilot or control system with high-resolution cell-level state information regarding battery pack 106 in real-time. Along with model-based estimation of state of health, the BAS 110 provides surveillance of individual cell degradation through monitoring and closed-loop control. Additionally, the BAS 110 provides forecasts of remaining energy in the battery pack 106, and will assist with trajectory planning, which enable deeper discharge (and thus enable higher ranges) from the battery pack 106. BAS 110 also contributes to the thermal management of battery pack 106 and passes information onto the pilot regarding the thermal state of battery pack 106. This helps to alleviate safety issues by preventing thermal runaway events. Finally, BAS 110 enables optimal charging and discharging protocols by preventing conditions of high degradation and unsafe operation, which will allow for more optimal economic conditions by minimizing time spent charging and maximizing pack and cell lifetime. In some embodiments, the individual cells of battery pack 106 may be monitored on an individual level while in other embodiments, battery pack 106 may be analyzed as a whole. One objective is to use as little tracking as possible to conserve computing resources and the number of sensors required to monitor battery pack 106.

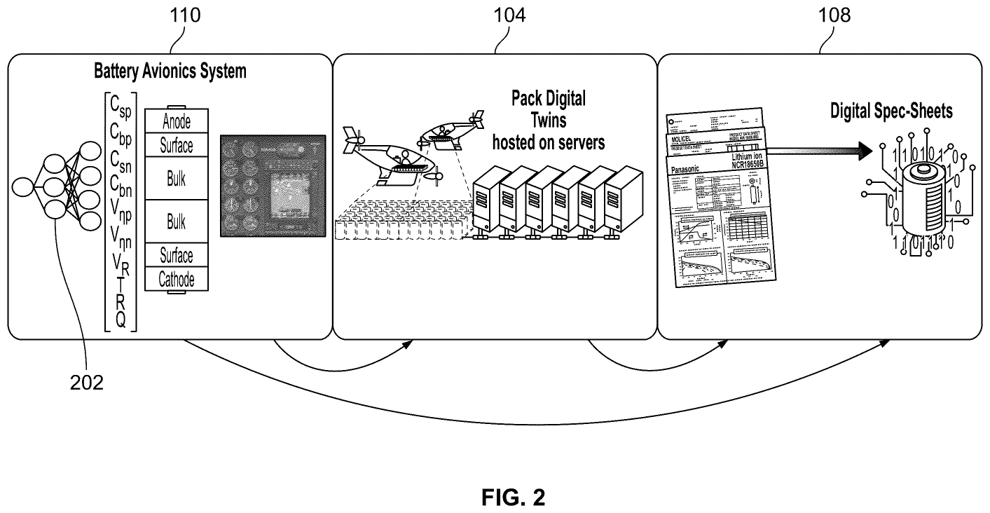

As shown in FIG. 2, BAS 110 may include a neural ODE 202 which is used to supplement predictions of battery degradation received from battery pack digital twin 104. When the data is uploaded from the battery pack digital twin model, BAS 110 will parameterize the model 202. Model 202 outputs new parameters that can improve its estimates for the internal state of the battery pack 106.

Battery Pack Digital Twin: To assist with aircraft design, including the design of control systems governing the trajectory, thermal management, and safety-critical instrumentation, a high-fidelity battery pack digital twin 104 is used. The battery pack digital twin 104 is crucial to realize the integrated operation of BAS 110 with other avionics components.

The on-ground cloud-based system 102, shown in FIG. 1 as reference 102, includes the battery pack digital twin 104 which is a model that simulates the actual battery pack 106, in some embodiments, on a cell-by-cell basis. The battery pack digital twin 104 can be optimally parameterized by the model. Building a physics-based model for new battery chemistry is time-consuming (>1 year) while purely data-driven methods require long testing, therefore, the model is preferably a combination physics-based model and data-driven model. The model may be a machine learning model, for example, a CNN or a neural ODE. In some embodiments, the Doyle-Fuller Newman (DFN) model, which is an electrochemistry-based lithium-ion battery model which represents solid-state and electrolyte diffusion dynamics and accurately predicts the current/voltage response, may be used as the physics-based portion of the model. The main function of battery pack digital twin 104 is parameter optimization. The parameter optimization attempts to determine what is happening inside the cells of the battery pack that causes the behavior of the battery pack to change over time. This may be accomplished by minimizing a loss function with respect to observable characteristics of the battery pack, such voltage, current, temperature, etc., which can be gathered directly from BAS 110. By optimizing for various properties it can be determined which degradation mechanisms are active.

The battery pack digital twin 104 is instrumental in trajectory planning and accounts for reserve requirements in real-time, optimizing charging protocol, and improving energy efficiency.

Digital Cell Spec-Sheets: Digital spec sheets 108 contain information that is passed from the cloud-based system 102 to update the BAS 110. A digital spec sheet 108 is a set of information that includes optimal parameters derived by the model, which are transferred via the digital spec sheets 108 to BAS 110.

BAS 110, and the battery pack digital twin 104, are cell chemistry and electrochemical model agnostic. To enable this feature, a digital specification sheet for batteries that are compatible with the battery pack digital twin 104 and BAS 110 were developed. Generated digital spec-sheets are loaded into the battery pack digital twin 104 and BAS 110, thereby enabling control of a diversity of batteries. Parameter estimation for battery models is limited by fitting only to observable quantities from cell testing data (i.e., voltage, current, temperature, etc.). Additional design and material-level information constrains the parameter estimation and new sensing features can be directly fused with a scientific machine learning approach.

The combination of the BAS software stack, including the digital specification sheets and cloud-based digital twins, improve range capability by >15% and usable life by >20%, fulfilling more use-cases with improved commercial viability via 10% cost reduction and safety during operation. The BAS software stack may be commercialized as a service for efficient operation and predictive maintenance of UAM aircraft. After the first deployment and validation in the UAM space, the BAS and the approaches within may find applications in other energy storage applications in the decarbonization infrastructure, including electric vehicles, grid storage, and beyond.

As would be realized by one of skill in the art, the disclosed systems and methods described herein can be implemented by a system comprising a processor and memory, storing software that, when executed by the processor, performs the functions comprising the method. For example, the training, testing and deployment of the model can be implemented by software executing on a processor.

As would further be realized by one of skill in the art, many variations on implementations discussed herein which fall within the scope of the invention are possible. Specifically, many variations of the architecture of the model coud be used to obtain similar results. The invention is not meant to be limited to the particular exemplary model disclosed herein. Moreover, it is to be understood that the features of the various embodiments described herein were not mutually exclusive and can exist in various combinations and permutations, even if such combinations or permutations were not made express herein, without departing from the spirit and scope of the invention. Accordingly, the method and apparatus disclosed herein are not to be taken as limitations on the invention but as an illustration thereof. The scope of the invention is defined by the claims which follow.

What is claimed:

1. A system comprising:
a battery avionics system for managing a battery pack powering an electric aircraft; and
one or more models, each model comprising a digital twin of the battery pack;
wherein observable data from the battery pack collected by the battery avionics system is used by the digital twins to optimize parameters for the battery pack; and
wherein the optimized parameters are communicated to the battery avionics system.

2. The system of claim 1 wherein the optimized parameters are communicated to the battery avionics system via one or more digital specification sheets.

3. The system of claim 1 wherein the one or more digital twins use a physics-based model combined with a data-driven model.

4. The system of claim 3 wherein the physics-based model is the Doyle-Fuller-Newman model.

5. The system of claim 1, the battery avionics system comprising a battery management system for managing the battery pack.

6. The system of claim 5, the battery avionics system optimizing management of the battery based on the one or more parameters provided by the digital twins.

7. The system of claim 1 wherein the observable data collected from the battery pack includes, voltage, current and temperature.

8. The system of claim 6 wherein the battery pack comprises a plurality of cells.

9. The system of claim 8 wherein the observable data is collected from each cell or from a portion of the plurality of cells in the battery pack.

10. The system of claim 1 wherein the battery avionics system and the digital twins are agnostic to cell chemistry and electrochemical properties of the battery pack.

11. The system of claim 1 wherein the battery management system is integrated or in communication with other avionics sub-systems of the aircraft.

12. The system of claim 11 wherein the battery avionics system and the digital twins are provided with a common battery specification sheet describing electrochemical and thermal performance metrics and material composition of the battery pack.

13. The system of claim 12 wherein the battery specification sheet is used by the digital twins as a differentiable modelling block enabled by a machine learning model.

14. The system of claim 1 wherein the battery avionics system provides real-time monitoring and control of the battery pack.

15. The system of claim 14 wherein the battery avionics system further provides integrated trajectory and recharge planning for the battery pack.

16. A method comprising:
receiving data characterizing a battery pack in an aircraft from a battery avionics system in the aircraft.
inputting the data to a model modelling a digital twin of the battery pack;
receiving optimized parameters for the battery pack from the model; and
communicating the optimized parameters to the battery avionics system.

17. The method of claim 16 wherein the model is a combination of a physics-based model combined with a data-driven model and further wherein the data received from the battery avionics system comprises externally observable data from the battery pack.

18. A method comprising:
reading observable data characterizing a battery pack powering an aircraft by a battery avionics system;
communicating the data off-aircraft to a model modelling a digital twin of the battery pack;
receiving optimized parameters for the battery pack from the model; and
using the optimized parameters to manage the battery pack.

19. The method of claim 18 further comprising:
further optimizing parameters received from the model using a neural ODE.

20. The method of claim 19 wherein the neural ODE provides predictions of battery degradation based on the optimized parameters.
